(19) United States
(12) Patent Application Publication
(10) Pub. No.: US 2012/0086612 A1
(43) Pub. Date: Apr. 12, 2012

(54) SYSTEMS AND METHODS OF TESTING ACTIVE DIGITAL RADIO ANTENNAS

(76) Inventors: Kevin Linehan, Rowlett, TX (US); Scott Sladek, Joliet, IL (US); John Kadala, Joliet, IL (US); Jonas Aleksa, Exeter, NH (US); Jonathon C. Veihl, New Lenox, IL (US)

(21) Appl. No.: 13/269,250

(22) Filed: Oct. 7, 2011

Related U.S. Application Data
(60) Provisional application No. 61/390,710, filed on Oct. 7, 2010.

(51) Int. Cl. G01R 29/10

(52) U.S. Cl. 343/703

(57) ABSTRACT

Systems and methods of testing active digital radio antennas are presented. Systems and methods can test the active digital radio antenna functioning as both a radio and as an antenna and can test both the transmit and receive performance of the antenna. An electromagnetic probe can scan the antenna to perform the testing and couple to the elements of the antenna using radio frequency signals propagated in the air, as opposed to direct cabling.

### CROSS-REFERENCE TO RELATED APPLICATIONS

This application claims priority to U.S. Provisional Patent Application No. 61/390,710 filed Oct. 7, 2010 and titled “Systems and Methods of Testing Active Digital Radio Antennas”. U.S. Application No. 61/390,710 is hereby incorporated by reference.

### FIELD

The present invention relates generally to active digital radio antennas. More particularly, the present invention relates to systems and methods for testing active digital radio antennas.

### BACKGROUND

Known active digital radio antennas can function as both a radio and as an antenna. For example, known active digital radio antennas can include an array of radiating elements and an array of radio elements, specifically transceivers or micro-radios. The elements of known active digital radio antennas can both transmit and receive signals.

To test a known active digital radio antenna, known systems and methods require that the antenna be at least partially disassembled and that a coaxial cable or other hard wire be physically connected to each element under test in the antenna. For example, active electronic components can be tested and calibrated using physical cable connections, and passive radiating elements can be tested separately. This can be a cumbersome, tedious, and time consuming task.

The prior art recognizes certain advantages to testing an active digital radio antenna without disassembling the antenna. Accordingly, in embodiments shown and described herein, the entire system as assembled (or as returned from the field) may be tested as a unit, including the interconnects and/or feed network between the active electronics and the passive radiating elements. Preferably, such systems and methods test the active digital radio antenna functioning as both a radio and as an antenna.

### SUMMARY

According to some embodiments, a method is provided that includes generating a test signal, transmitting the test signal to a fully assembled antenna, the fully assembled antenna transmitting a radio frequency signal based on the test signal, receiving the signal transmitted by the fully assembled antenna, measuring the signal received by the fully assembled antenna, and comparing the measured signal with the test signal. The radio frequency signal can propagate in ambient atmosphere when transmitted from the fully assembled antenna.

According to some embodiments, another method is provided that includes generating a test signal, transmitting the test signal to an electromagnetic probe, the electromagnetic probe transmitting the test signal via radio frequency, a fully assembled antenna receiving a radio frequency signal from the electromagnetic probe, measuring the radio frequency signal received by the fully assembled antenna, and comparing the measured signal with the test signal. The test signal can propagate in ambient atmosphere when transmitted from the electromagnetic probe.

According to some embodiments, another method is provided that includes obtaining reference amplitude and phase, each transceiver in a fully assembled antenna transmitting, via corresponding radiating elements, a radio frequency signal, successively measuring amplitude and phase of the radio frequency signal transmitted by each of the transceivers in the fully assembled antenna, via the corresponding radiating elements, relative to the reference amplitude and phase, and estimating a beam pattern transmitted by the fully assembled antenna. The radio frequency signal transmitted from each transceiver can propagate in ambient atmosphere for measurement.

According to some embodiments, another method is provided that includes generating a pure test tone, transmitting the pure test tone to an electromagnetic probe, the electromagnetic probe successively transmitting the pure test tone to a fully assembled antenna, successively measuring amplitude and phase of a signal received by the fully assembled antenna, and estimating a beam pattern received by the fully assembled antenna. The pure test tone transmitted from the electromagnetic probe can propagate in ambient atmosphere from the electromagnetic probe to the fully assembled antenna.

According to some embodiments, another method is provided that includes generating a wave tone with known amplitude and phase, transmitting the wave tone with known amplitude and phase to an electromagnetic probe, the electromagnetic probe transmitting the wave tone with known amplitude and phase to a fully assembled antenna, measuring a power level of a signal received by the fully assembled antenna, and calibrating the fully assembled antenna. The wave tone transmitted from the electromagnetic probe can propagate in ambient atmosphere from the electromagnetic probe to the fully assembled antenna.

According to some embodiments, another method is provided that includes a fully assembled antenna transmitting a first signal with known amplitude and phase, measurement equipment receiving a second signal from the fully assembled antenna, measuring amplitude and phase of the second signal received by the measurement equipment, and calibrating the fully assembled antenna. The first signal transmitted by the fully assembled antenna can propagate in ambient atmosphere from the fully assembled antenna to the measurement equipment.

According to some embodiments, another method is provided that includes an electromagnetic probe transmitting and receiving known radio frequency signals propagating in ambient air to and from the fully assembled antenna, and measuring signals transmitted by and received at the fully assembled antenna and the electromagnetic probe.

According to some embodiments, a system is provided that includes a fully assembled active digital radio antenna, and an electromagnetic probe. The electromagnetic probe can transmit and receive known radio frequency signals propagated in ambient air to and from the fully assembled antenna, and signals transmitted by and received at the fully assembled antenna and the electromagnetic probe can be measured.

### BRIEF DESCRIPTION OF THE DRAWINGS

FIG. 1 is a perspective view of a system for testing an active digital radio antenna;

FIG. 2A and FIG. 2B are charts displaying exemplary test results generated from testing an active digital radio antenna;

FIG. 3 is a block diagram of an electromagnetic test probe and an active digital radio antenna configured for measuring a receive path;

FIG. 4 is a block diagram of an electromagnetic test probe and an active digital radio antenna configured for measuring a co-polarized transmit path;

FIG. 5 is a block diagram of an electromagnetic test probe and an active digital radio antenna configured for measuring a cross-polarized transmit path;

FIG. 6 is a block diagram of an electromagnetic test probe and an active digital radio antenna configured for measuring a co-polarized receive path;

FIG. 7 is a block diagram of an electromagnetic test probe and an active digital radio antenna configured for measuring a cross-polarized receive path;

FIG. 8 is a block diagram of an electromagnetic test probe and an active digital radio antenna configured for measuring transmit path co-polarized isolation between adjacent dipoles;

FIG. 9 is a block diagram of an electromagnetic test probe and an active digital radio antenna configured for measuring receive path co-polarized isolation between adjacent dipoles;

FIG. 10 is a block diagram of an electromagnetic test probe and an active digital radio antenna configured for characterizing the transmit filter path of a duplexer;

FIG. 11 is a block diagram of an electromagnetic test probe and an active digital radio antenna configured for characterizing the receive filter path of a duplexer;

FIG. 12 is a flow diagram of a novel method of testing the radio transmitting performance of a transceiver in an active digital radio antenna;

FIG. 13 is a flow diagram of a novel method of testing the radio receiving performance of a transceiver in an active digital radio antenna;

FIG. 14 is a flow diagram of a novel method of testing the transmitted beam pattern of an active digital radio antenna;

FIG. 15 is a flow diagram of a novel method of testing the received beam pattern of an active digital radio antenna;

FIG. 16 is a flow diagram of a novel method of calibrating a receive path of an active digital radio antenna; and

FIG. 17 is a flow diagram of a novel method of calibrating a transmit path of an active digital radio antenna.

### DETAILED DESCRIPTION

While this invention is susceptible of embodiments in many different forms, there are shown in the drawings and will be described herein in detail specific embodiments thereof with the understanding that the present disclosure is to be considered as an exemplification of the principles of the invention. It is not intended to limit the invention to the specific illustrated embodiments.

Embodiments described include systems and methods of testing an active digital radio antenna without disassembling the antenna. Examples of such active digital radio antennas include International Application No. PCT/US09/66345, U.S. Pat. No. 6,621,469, and U.S. Publication No. 2009/0252205, the disclosures of which are hereby incorporated by reference.

Systems and methods according to some embodiments can test the active digital radio antenna functioning as both a radio and as an antenna and can test both the transmit and receive performance of the active digital radio antenna. In accordance with some embodiments, an electromagnetic probe can scan an active digital radio antenna to perform the testing. The electromagnetic probe can be a single element antenna and can couple to the elements of the antenna using radio frequency (RF) signals propagated in the air, as opposed to direct cabling.

Each element of the active digital radio antenna can be tested individually using the electromagnetic probe. Thus, each radiating element and each transceiver can be individually tested to identify and specify any defective elements in the antenna.

Several tests can be performed on the active digital radio antenna. For example, the radio performance can be tested. This can include both the transmit and receive performance as well as the simultaneous transmit and receive performance. The beam pattern of the active digital radio antenna can also be tested. This can also include both the transmit and receive performance. Finally, the transmit and receive paths of the active digital radio antenna can be calibrated.

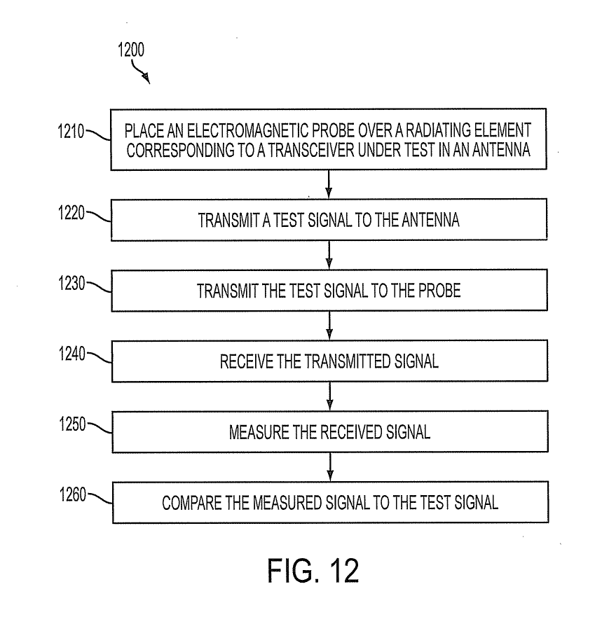

FIG. 12 is a flow diagram of a novel method 1200 of testing the radio transmitting performance of a transceiver in the active digital radio antenna. As seen in FIG. 12, an electromagnetic probe can be placed over a radiating element corresponding to a transceiver under test in the antenna as in 1210.

Then, a signal generator can transmit a digital test signal to the antenna as in 1220, and the transceiver under test can transmit the test signal, via the radiating element, to the probe as in 1230. In some embodiments, the test signal can be in WCDMA waveform, and in some embodiments, the signal generator can transmit the test signal to the antenna via a fiber optic cable.

As seen in FIG. 12, the electromagnetic probe can receive the signal being transmitted by the transceiver as in 1240. Thus, a direct cable between the radiating element of the antenna and the electromagnetic probe is not necessary. The signal transmitted by the transceiver under test and thus, received by the electromagnetic probe, can be measured as in 1250 and compared to the test signal as in 1260. If the measured signal is different than the test signal, then systems and methods can determine that the radio transmitting performance of the transceiver under test is defective.

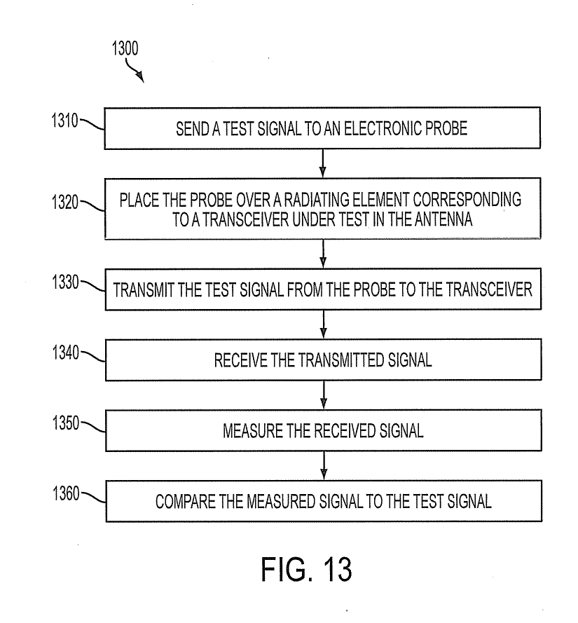

FIG. 13 is a flow diagram of a novel method 1300 of testing the radio receiving performance of a transceiver in the active digital radio antenna. As seen in FIG. 13, a signal generator can send a test signal to an electromagnetic probe as in 1310. In some embodiments, the test signal can be in WCDMA format, and in some embodiments, the signal generator can transmit the test signal to the electromagnetic probe via a fiber optic cable.

The electromagnetic probe can be placed over a radiating element corresponding to a transceiver under test in the antenna as in 1320. Then, the electromagnetic probe can transmit the test signal to the transceiver as in 1330, and the transceiver can receive the signal as in 1340. The signal received by the transceiver can be measured as in 1350 and compared to the test signal transmitted by the electromagnetic probe as in 1360. If the measured signal is different than the test signal, then systems and methods can determine that the radio receiving performance of the transceiver under test is defective.

After the methods 1200 and 1300 shown in FIG. 12 and FIG. 13 are completed for a first transceiver in the antenna, that is, after the performance testing and measurements of the first transceiver is complete, the electromagnetic probe can individually test every other transceiver in the antenna. That is, the methods 1200 and 1300 shown in FIG. 12 and FIG. 13, respectively, can be executed for each transceiver in the antenna.

In some embodiments, more than one transceiver may correspond to a single radiating element. For example, cross-polarization of an emitted signal may require two transceivers. In these examples, the electromagnetic probe may test all of the transceivers associated with a radiating element before moving to the next radiating element.

In accordance with some embodiments, the methods 1200 and 1300 shown in FIG. 12 and FIG. 13, respectively, can be executed substantially simultaneously for each transceiver in the antenna. That is, the transmit and receive performance capabilities of each radiator and transceiver can be measured substantially simultaneously as the probe is positioned directly above it. In some systems and methods, the bit-error rate through the active antenna transmit and receive paths can be measured.

It is to be understood that embodiments are not limited to WCDMA format, or to single standard antennas. Alternate embodiments can include 2G (GSM, CDMA), 3G (UMTS, WCDMA, EVDO, TD-SCDMA) or 4G (LTE, WiMAX, TD-LTE) systems. Additionally, some embodiments can test antennas providing combinations of such signals.

For example, in one alternate embodiment, the system can be configured to test and calibrate an active digital radio antenna that produces and receives multi-standard waveforms, e.g., a waveform that includes signals under the 2G standard and the 4G standard. In these embodiments, the electromagnetic probe may be configured to scan each standard separately (e.g. 2G in one scan and 4G in another scan). In some embodiments, the electromagnetic probe may also be configured to scan combined multi-standard waveforms (e.g. 2G and 4G simultaneously).

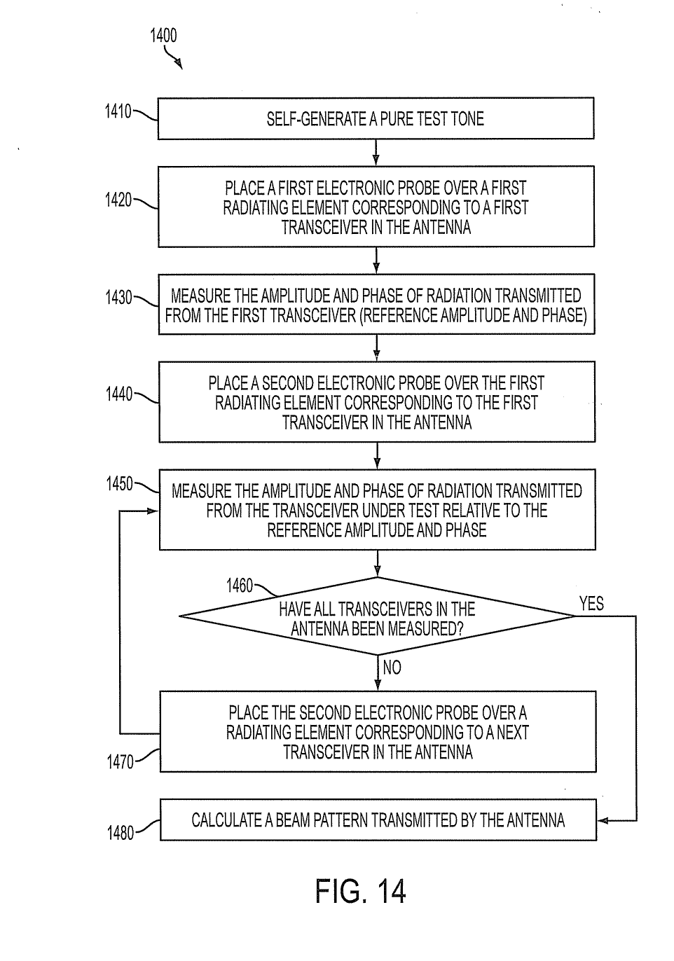

FIG. 14 is a flow diagram of a novel method 1400 of testing the transmitted beam pattern of the active digital radio antenna. As seen in FIG. 14, each transceiver in the antenna can self-generate a pure test tone as in 1410. Then, a first electromagnetic probe can be placed over an area of the antenna housing corresponding to a first radiating element as in 1420. The first electromagnetic probe can measure the amplitude and phase of radiation transmitted from a first transceiver and through the first radiating element as in 1430. In subsequent measurements, the amplitude and phase measured by the first electromagnetic probe can be used as a reference amplitude and phase.

As seen in FIG. 14, after the first electromagnetic probe obtains the reference amplitude and phase as in 1430, a second electromagnetic probe can measure amplitude and phase relative to the reference amplitude and phase for each radiating element in the antenna, including the first radiating element.

For example, the second electromagnetic probe can be placed over an area of the antenna housing corresponding to the first radiating element as in 1440. Then, the second electromagnetic probe can measure the amplitude and phase of radiation transmitted from the first transceiver and through the first radiating element as in 1450. The amplitude and phase measured by the second electromagnetic probe can be made relative to the reference amplitude and phase.

The method 1400 can determine if all transceivers have been measured as in 1460. If not, then the method 1400 can move and place the second electromagnetic probe over an adjacent radiating element corresponding to an adjacent transceiverin the antenna as in 1470. Then, the method 1400 can measure the amplitude and phase, of radiation transmitted from the transceiver under test and through the radiating element under test as in 1450. The amplitude and phase measured by the second electromagnetic probe can be made relative to the reference amplitude and phase.

After the second electromagnetic probe completes measurement of radiation transmitted by all of the radiating elements in the antenna, the amplitudes and phases measured by the second electromagnetic probe can be considered a collection of amplitudes and phases.

When testing the active digital radio antenna, the distance between the antenna and the electromagnetic probe can be fixed. Accordingly, a beam pattern transmitted by the antenna as a whole can be calculated as in 1480 using the measured collection of amplitude and phases, the fixed distance between the antenna and the probe, and a known frequency. That is, the near field measurement scan can be used to estimate the beam pattern generated in a far field to verify that the antenna is operating correctly, is calibrated correctly, and is correctly forming a beam.

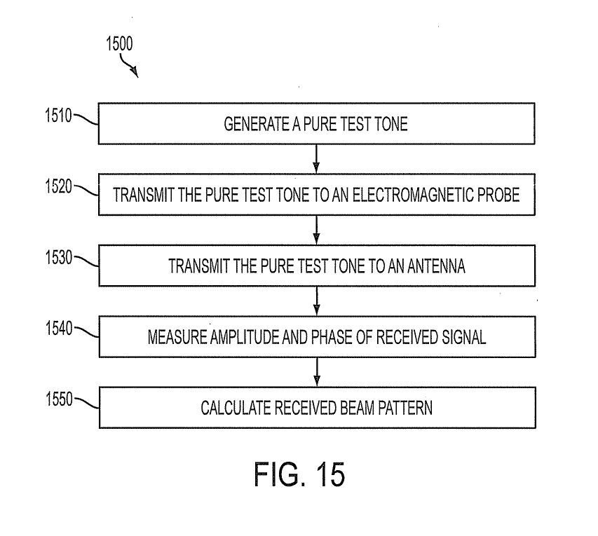

FIG. 15 is a flow diagram of a novel method of testing the received beam pattern of the active digital radio antenna. As seen in FIG. 15, a signal generator can generate a pure test tone as in 1510. The pure test tone can be transmitted from the signal generator to an electronic probe as in 1520 and from the electronic probe to the antenna as in 1530.

As seen in FIG. 15, the active electronics of the antenna can measure the amplitude and phase of the received signal as in 1540. Then, the received beam pattern can be calculated using the measured amplitude and phase as in 1550.

When testing the active digital radio antenna, the distance between the antenna and the electromagnetic probe is fixed. Accordingly, the method 1500 can calculate the beam pattern received by the antenna as in 1550 using the measured amplitude and phase received by the antenna, the fixed distance between the antenna and a probe, and a known frequency. That is, the near field measurements can be used to estimate the beam pattern received from a far field to verify that the antenna is operating correctly, is calibrated correctly, and is correctly forming a received beam.

For the antenna to operate correctly in the field, the amplitude and phase of each transmit and receive path must be initially calibrated after assembly in the factory. Thus, in accordance with some embodiments, transmit and receive paths of the active digital radio antenna can be calibrated electromagnetically and without disassembly of the antenna.

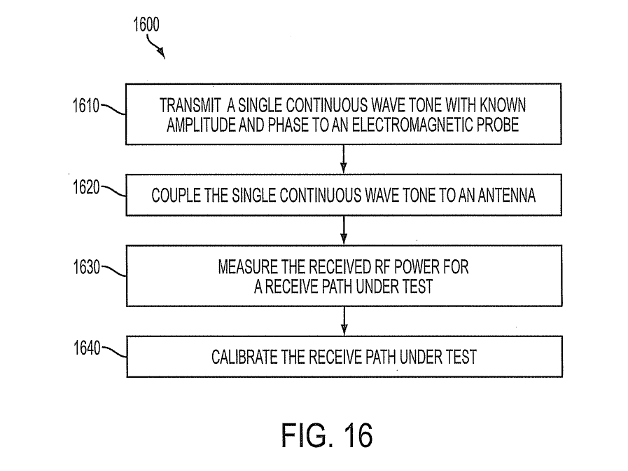

FIG. 16 is a flow diagram of a novel method 1600 of calibrating a receive path of the active digital radio antenna. As seen in FIG. 16, a signal generator can transmit a single continuous wave tone with known amplitude and phase to an electromagnetic test probe as in 1610. Then, the electromagnetic probe can couple the single continuous wave tone to the antenna as in 1620.

As seen in FIG. 16, the received RF power for the receive path under test can be measured as in 1630. That is, the power level of the received signal can be measured. Then, the method 1600 can calibrate the receive path under test as in 1640 using the measured power level of the received signal and the known amplitude and phase of the transmitted signal.

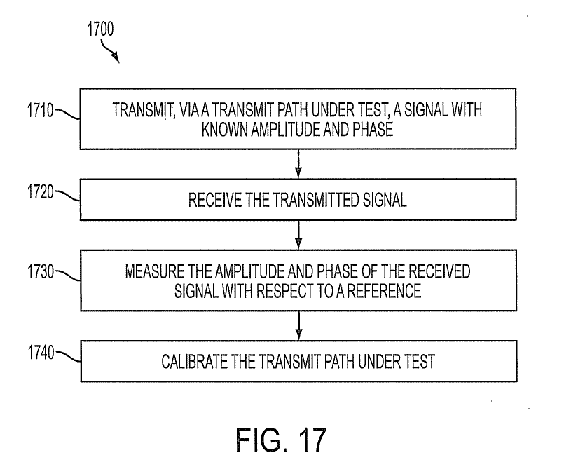

FIG. 17 is a flow diagram of a novel method 1700 of calibrating a transmit path of the active digital radio antenna. As seen in FIG. 17, a transceiver of the antenna can transmit, via a transmit path under test, a signal with known amplitude and phase as in 1710. Then, the signal can be received by measurement equipment as in 1720. For example, the signal can be received by an electromagnetic test probe.

As seen in FIG. 17, the measurement equipment can measure the amplitude and phase of the received signal with respect to a reference as in 1730. Then, the method 1700 can calibrate the transmit path of the antenna as in 1740 using the measured amplitude and phase and the known amplitude and phase.

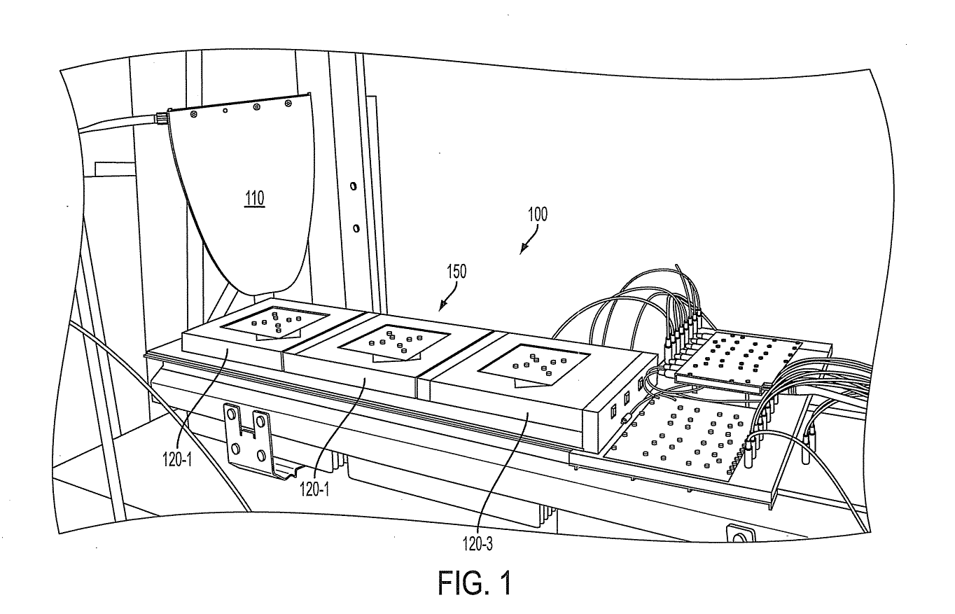

The methods illustrated in FIGS. 12-17 and others in accordance with embodiments of the present invention can be implemented with the system 100 shown in FIG. 1. As seen in FIG. 1, an electromagnetic probe 110 can be placed over a first radiating element 120-1 of an active digital radio antenna 150. For illustration purposes, the radome of the antenna 150 is removed in FIG. 1. The transceivers of the antenna 150 can be housed below the radiating elements 120-1, 120-2, 120-3.

As would be understood by those of skill in the art, the electromagnetic probe 110 and the active digital radio antenna 150 can be coupled to a signal generator and a spectrometer via fiber optic cables. When fully assembled, a radome can be placed over the radiating elements 120-1, 120-2, 120-3.

In some embodiments, the active digital radio antenna 150 can include up to sixteen radiating elements: two arrays with each array including eight elements. Tests, including those described in FIGS. 12-17 and others in accordance with embodiments of the present invention, can be performed on each antenna element individually using the system 100 or other systems in accordance with embodiments of the present invention. In some embodiments, each element can be tested in approximately 2.6 minutes, and each array can be tested in approximately 21 minutes.

In accordance with some embodiments, as many as nineteen tests can be performed on each element. For example, the following tests can be performed on each element in the antenna using a single CDMA carrier in the middle of the transmit and receive bands: ACLR (Adjacent Channel Leakage Ratio) 5/10 MHz spacing Lo/Hi side; Max Power Out; Occupied Bandwidth; Frequency Error; Spectrum Emission Mask Lo/Hi side; Spurious Emission; Internal CW 2 Tone 3rd/5th Order Lo/Hi Side 1 MHz Spacing; Rx Power Detector @−75 dBm; BER (Bit Error Rate) Lock @−75 dBm; and RTWP (Receive Total Wideband Power) Carrier 0/1.

The ACLR (Adjacent Channel Leakage Ratio) 5/10 MHz spacing Lo/Hi side test can include a spectrum analyzer measuring the antenna's adjacent channel power level 5 and 10 MHz above and below the WCDMA carrier center frequency. In some embodiments, to pass this test, the 5 MHz level must be below −47 dBm, and the 10 MHz level must be below −52 dBm.

The Max Power Out test can include a spectrum analyzer measuring the antenna's maximum RF power output at a desired frequency. In some embodiments, the desired power level is 34 dBm+/−2 dBm.

The Occupied Bandwidth and Frequency Error tests can include the spectrum analyzer measuring the antenna's single carrier transmitted signal based on an occupied bandwidth of 5 MHz. The spectrum analyzer can also measure the antenna's single carrier transmitted frequency error as the difference between the measured and assigned +/−12 Hz.

The Spectrum Emission Mask Lo/Hi side test can include the spectrum analyzer measuring the antenna's single carrier transmitted emission close to the assigned channel bandwidth of the wanted signal using a defined mask.

The Spurious Emission test can include the spectrum analyzer measuring the antenna's single carrier transmitted emissions that are caused by unwanted transmitter effects such as harmonious, parasitic, or intermodulation products.

The Internal CW 2 Tone 3rd/5th Order Lo/Hi Side 1 MHz Spacing test can include the spectrum analyzer measuring the antenna's two internally generated continuous wave tones transmitted emissions and the 3rd and 5th order intermodulation products.

The Rx Power Detector @−75 dBm test can include recording the antenna's internal receive power detector reading for a desired transceiver and array. The detector level can be set by inputting an RF signal at a desired frequency and −75 dBm level out of the probe and received by the antenna.

The BER (Bit Error Rate) Lock @−75 dBm test can include measuring the internal BER. In embodiments, bit error rate can be measured by inputting an RF measurement signal with known BER to the input of the antenna's receiver. BER can be +/−10% of the BER generated by the RF signal source and calculated over at least 50,000 bits.

The RTWP (Receive Total Wideband Power) Carrier 0/1 test can include recording the antenna's internal RTWP detector. In embodiments, the desired value of RTWP is −105 dBm on each of the two carriers. Elevated levels can indicate RF interference.

Other tests not specifically described herein can come within the spirit and scope of the present invention. For example, the Rx IIP3 performance of each receive path in the antenna can be measured, blocking tests can be performed, cross-polarization isolation for transmit or receive frequencies for a single dipole can be measured, isolation between adjacent or non-adjacent dipoles can be measured, and the duplexer functionality of the antenna can be characterized.

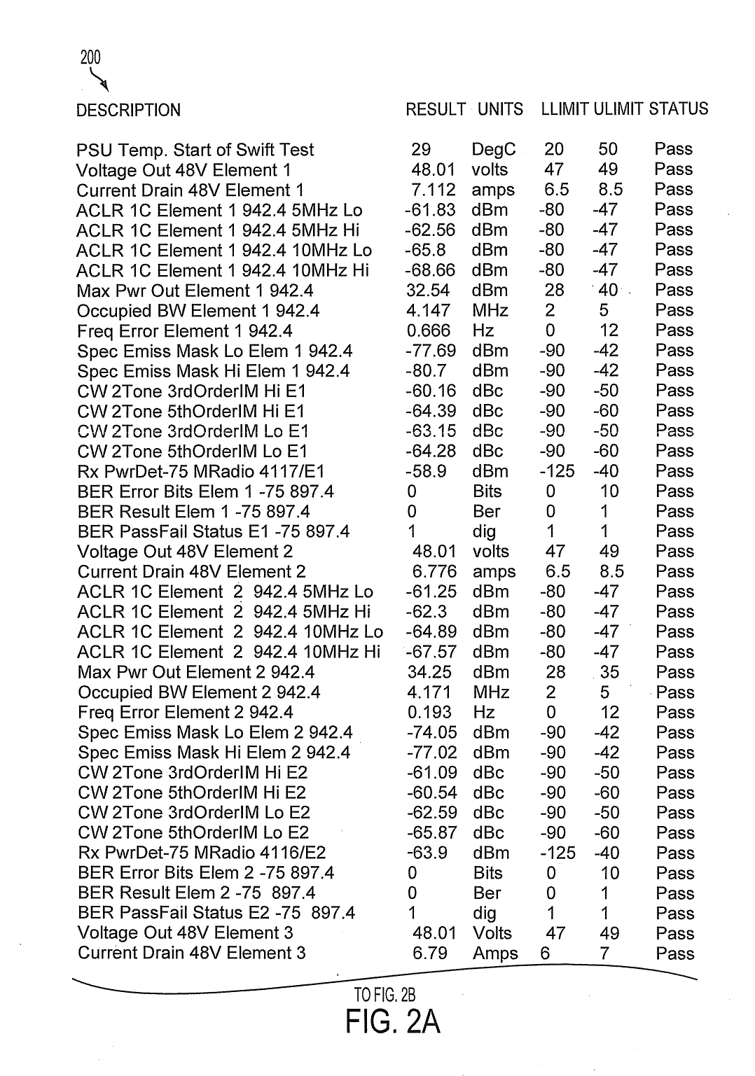

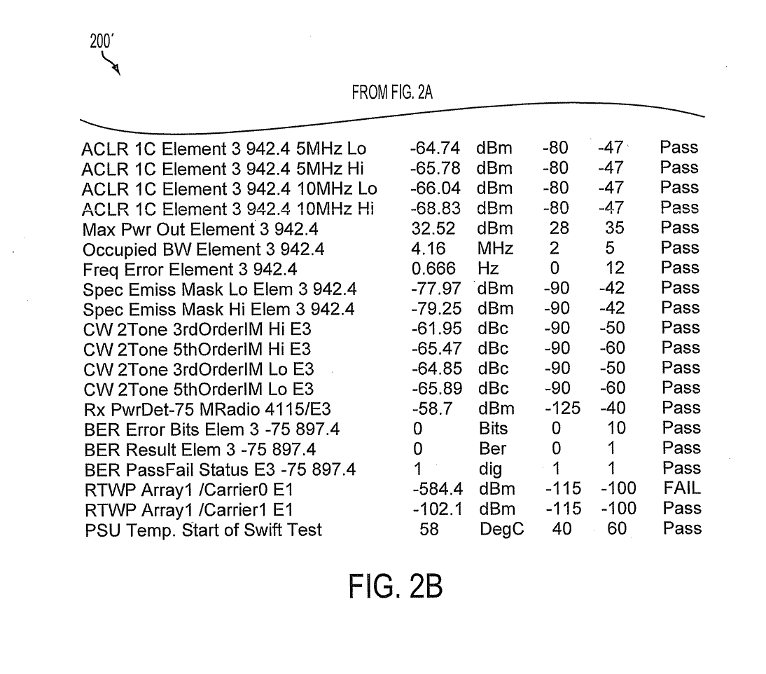

FIG. 2A and FIG. 2B are charts 200 and 200′, respectively displaying exemplary test results generated by testing an active digital radio antenna. FIGS. 2A and 2B show the results from testing three transceivers of the antenna. To perform these tests on the active digital radio antenna, an electromagnetic test probe can be employed as described above and in more detail herein.

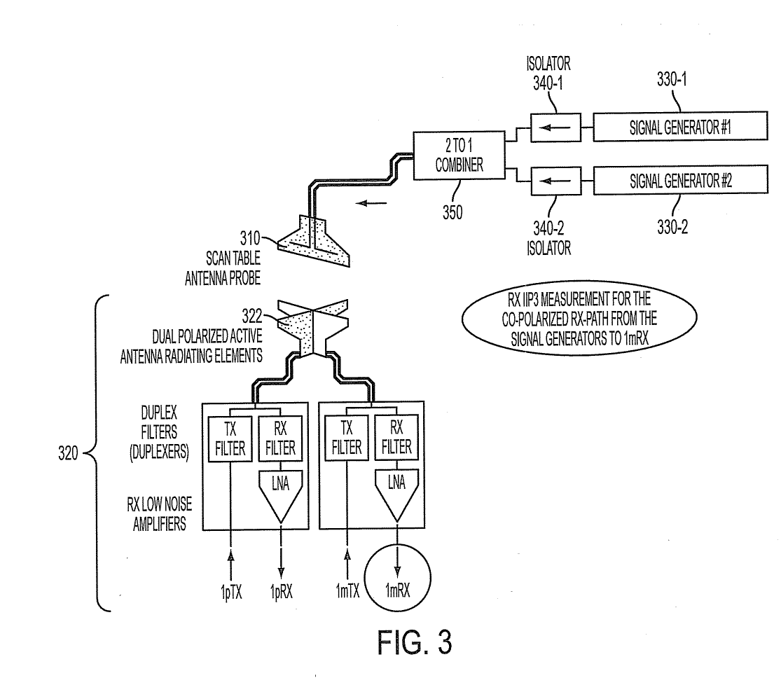

FIG. 3 is a block diagram of an electromagnetic test probe 310 and an active digital radio antenna 320 configured for measuring a receive path. To measure the Rx IIP3 performance of the co-polarized receive path 1mRX, two signal generators 330-1, 330-2 can be employed.

A first signal generator 330-1 can generate a first single continuous wave tone, and a second signal generator 330-2 can generate a second single continuous wave tone. The first and second tones can pass through first and second isolators 340-1 and 340-2 and can be combined using a 2-way combiner 350. The combined signal can be fed to the electromagnetic probe 310, and the probe 310 can then transmit the combined signal to a dual polarized active antenna radiating element 322 of the active digital radio antenna 320.

When only one continuous wave tone is transmitted to the antenna 320, the receive RF power for any particular Rx path in the active antenna can be measured. Thus, the power level of an applied Rx signal can be measured. However, when the combined signal is transmitted to the antenna 320, the third order product in any particular Rx path in the antenna 320 can be measured. Thus, the Rx IIP3 performance of each individual Rx path in the antenna 320 can be characterized.

A variety of blocking tests are required in the industry to demonstrate 3GPP compliance. Such blocking tests are typically performed at the design verification level and not at the production level.

For example, some blocking tests can involve combining a desired signal at a normal operating level (e.g. −115 dBm) with a WCDMA interfering signal at 10 MHz offset @−40 dBm as well as a continuous wave signal at 20 MHz offset @−15 dBm. To satisfy the 3GPP compliance requirements, some standards require that the system demonstrate a certain bit error rate level, such as, for example, 0.0001. In known systems and methods, these and other similar tests can be performed with discrete signal generator sources that can be combined and connected directly into the antenna port with a coaxial cable.

However, in embodiments described herein, discrete signal generator sources can be combined and connected to an electromagnetic probe, for example, probe 310, and the bit error rate level can be monitored. The probe 310 can then transmit the signals to the active antenna element under test by propagating the transmitted signals in ambient atmosphere from the probe to the antenna. Accordingly, blocking tests can be performed without removing the radome of the antenna, and 3GPP compliance can determined while keeping the antenna fully intact.

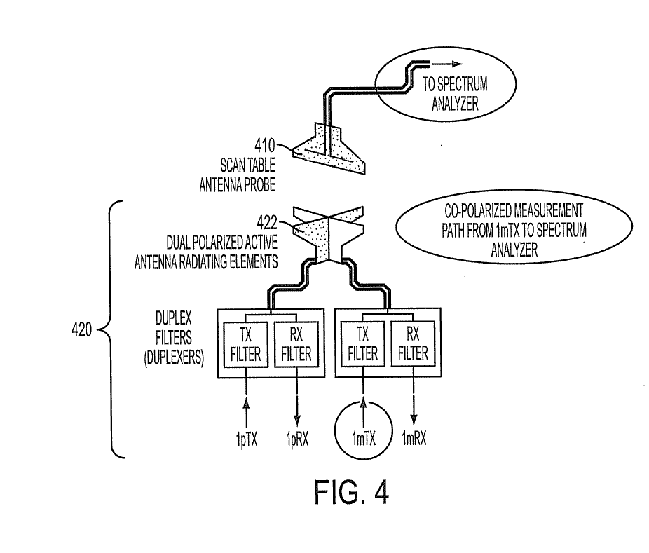

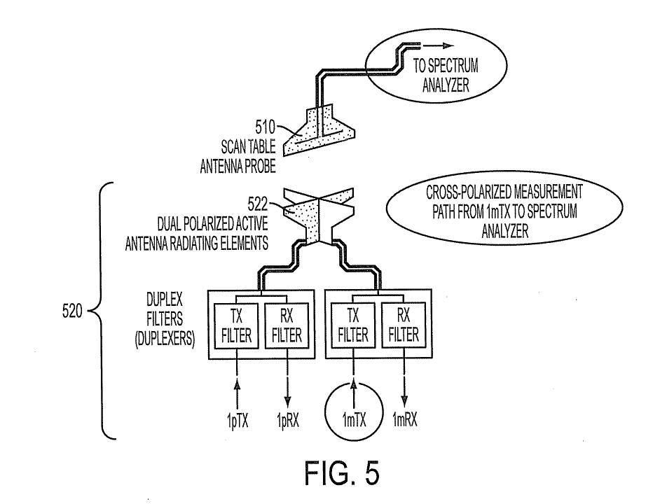

FIG. 4 is a block diagram of an electromagnetic test probe 410 and an active digital radio antenna 420 configured for measuring a co-polarized transmit path, and FIG. 5 is a block diagram of an electromagnetic test probe 510 and an active digital radio antenna 520 configured for measuring a cross-polarized transmit path.

As seen in FIG. 4, an electromagnetic probe 410 can be aligned so that it is co-polarized with a radiating element 422 under test. To test the transmit frequencies, the radiating element 422 can transmit a signal, via the transmit path under test 1mTx, to the probe 410, and the power level received by the probe 410 can be measured by a spectrum analyzer connected to the probe 410. The measured power level can be considered the co-polarized measurement.

To obtain a cross-polarized measurement, the probe can be rotated to an orthogonal cross-polarization position as seen in FIG. 5. To test the transmit frequencies, the radiating element 522 can transmit a signal, via the transmit path under test 1mTx, to the probe 510. The power level received by the probe 510 can be measured at a spectrum analyzer connected to the probe 510, and the measured power level can be considered the cross-polarized measurement. As explained herein, in some embodiments, the difference between the co-polarized measurement and the cross-polarized measurement can be used to determine the cross-polarization isolation for a particular dipole.

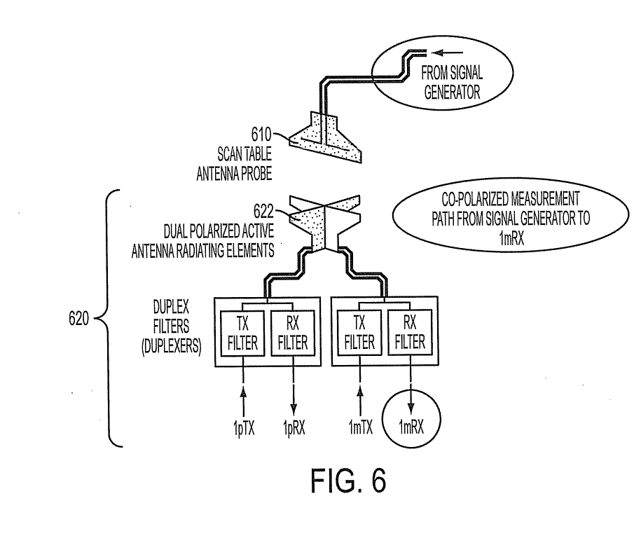

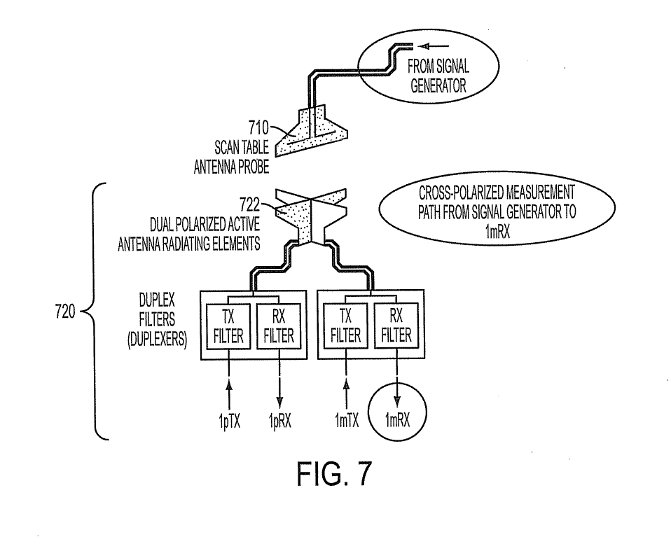

FIG. 6 is a block diagram of an electromagnetic test probe 610 and an active digital radio antenna 620 configured for measuring a co-polarized receive path, and FIG. 7 is a block diagram of an electromagnetic test probe 710 and an active digital radio antenna 720 configured for measuring a cross-polarized receive path. To test the receive frequencies, a signal transmitted from the co-polarized or cross-polarized probe 610, 710, respectively, can be received by the active digital radio antenna 620 or 720, and the received power can be measured in the antenna receive path 1mRx under test.

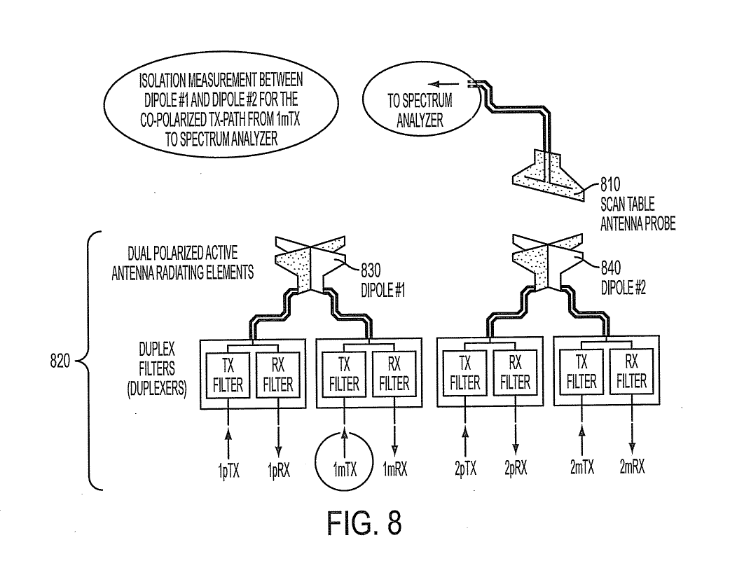

FIG. 8 is a block diagram of an electromagnetic test probe 810 and an active digital radio antenna 820 configured for measuring transmit path co-polarized isolation between adjacent dipoles 830, 840. To test transmit path co-polarized isolation between adjacent dipoles 830, 840, the electromagnetic probe 810 can be aligned so that it is co-polarized with the dipole 830 under test. To test the transmit frequencies, the dipole 830 can transmit a signal, via a transmit path under test, and the power level of the signal received by the electromagnetic probe 810 can be measured by a spectrum analyzer connected to the probe 810. This can be considered the co-polarized measurement of the first dipole 830.

Then, the electromagnetic probe 810 can be moved to so that it is co-polarized with a second, adjacent dipole 840. The dipole element 840 can transmit a signal, and the power level received by the probe 810 can be measured by the spectrum analyzer connected to the probe 810. This can be considered the co-polarized measurement of the second dipole 840.

The difference between the co-polarized measurement of the first dipole 830 and the co-polarized measurement of the second, adjacent dipole 840 can be used to determine the isolation between transmit paths under test of the dipoles 830, 840. In embodiments, the electromagnetic probe 810 can also be placed for measuring isolation with respect to other, non-adjacent elements (not shown).

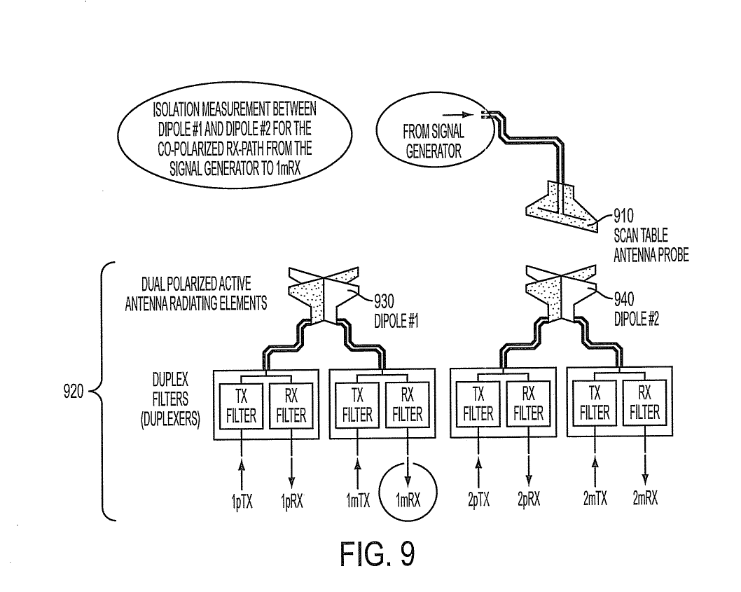

FIG. 9 is a block diagram of an electromagnetic test probe 910 and an active digital radio antenna 920 configured for measuring receive path co-polarized isolation between adjacent dipoles 930, 940. To test receive path co-polarized isolation between adjacent dipoles 930, 940, the electromagnetic probe 910 can be aligned so that it is co-polarized with a dipole 930 under test. To test the receive frequencies, the dipole 930, via a receive path under test, can receive a signal transmitted from the probe 910, and the power level of the signal received in the receive path under test can be measured. This can be considered the co-polarized measurement of the first dipole 930.

Then, the electromagnetic probe 910 can be moved to so that it is co-polarized with a second, adjacent dipole 940. The dipole 940 can receive a signal transmitted from the probe 910, and the power level of the signal received in the receive path under test can be measured. This can be considered, the co-polarized measurement of the second dipole 940.

The difference between the co-polarized measurement of the first dipole 930 and the co-polarized measurement of the adjacent dipole 940 can be used to determine the isolation between receive paths of the dipoles 930, 940. In embodiments, the electromagnetic probe 910 can also be placed for measuring isolation with respect to other, non-adjacent elements (not shown).

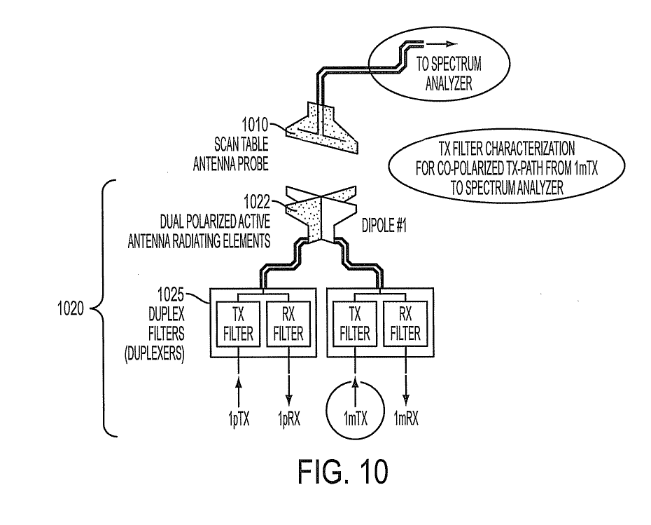

FIG. 10 is a block diagram of an electromagnetic test probe 1010 and an active digital radio antenna 1020 configured for characterizing the transmit filter path of a duplexer 1025. Each antenna element 1022 can include a duplex type filter: a duplexer 1025. To characterize the transmit filter path of the duplexer 1025 under test, the electromagnetic probe 1010 can be aligned so that it is co-polarized with the radiating element 1022 under test.

To test the transmit frequencies, the radiating element 1022, via the transmit filter path of the duplexer 1025 under test, can transmit a signal at a first frequency and power level, and the power level received by the electromagnetic probe 1010 can be measured. This can be considered the co-polarized measurement.

Then, the radiating element 1022, via the transmit filter path of the duplexer 1025 under test, can transmit a signal at a second frequency, and the power level received by the probe can be measured again. Signals with varying frequencies can continue to be transmitted by the element 1022, via the transmit filter path of the duplexer 1025 under test, and power levels can continue to be measured by the probe 1010. Thus, a frequency response of the transmit filter path of the duplexer 1025 can be characterized.

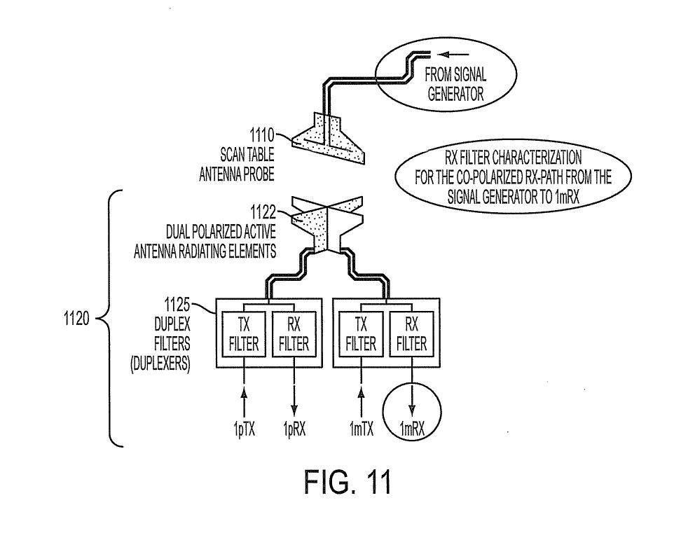

FIG. 11 is a block diagram of an electromagnetic test probe 1110 and an active digital radio antenna 1120 configured for characterizing the receive filter path of a duplexer 1125. To characterize the receive filter path of the duplexer 1125 under test, the electromagnetic probe 1110 can be aligned so that it is co-polarized with the radiating element 1122 under test.

To test the receive frequencies, a signal having a first frequency and power level can be generated by an external signal generator. The signal can be transmitted to the probe 1110, and the probe 1110 can transmit the signal to the antenna 1120. The power level of the signal received via the receive filter path of the duplexer 1125 under test can be measured. This can be considered the co-polarized measurement.

Then, the probe 1110 can transmit a signal at a second frequency, and the power level received via the receive filter path of the duplexer 1125 under test can be measured again. Signals with varying frequencies can continue to be transmitted by the probe 1110, and power levels can continue to be measured by the antenna 1120. Thus, a frequency response of the receive filter path of the duplexer 1125 can be characterized.

Passive inter-modulation (PIM) can be generated in the passive components of the active digital radio antenna shown and described. For example, when electrical connections between conductors are loose and behave as diodes, they can cause undesired mixing in the presence of RF currents. For example, when transmit signals of the active digital radio antenna operate at a high power (e.g. 5 W), these signals can mix. The mixed product can manifest in the receive band and appear as noise. PIM can be caused by loose metal connections and/or joints that are improperly soldered together, for example.

In some embodiments, an active digital radio antenna can be measured and tested for PIM performance to test the integrity of the passive signal paths within the antenna. For example, two transmit test tones from a given transceiver can be generated and propagated through the passive RF path. The noise floor of the receive signal path for the given transceiver can be monitored for PIM by the transceiver. In some embodiments, the 3rd, 5th, 7th, and higher order harmonics of the receive signal can also be measured.

Systems and methods of testing an active digital radio antenna described herein have been described with reference to testing the antenna in the near-field. However, in some embodiments, active digital radio antennas can also be tested in the far-field.

From the foregoing, it will be observed that numerous variations and modifications may be effected without departing from the spirit and scope of the invention. It is to be understood that no limitation with respect to the specific system or method illustrated herein is intended or should be inferred. It is, of course, intended to cover by the appended claims all such modifications as fall within the sprit and scope of the claims.

What is claimed is:

1. A method comprising:
generating a test signal;
transmitting the test signal to a fully assembled antenna;
the fully assembled antenna transmitting a radio frequency signal based on the test signal;
receiving the signal transmitted by the fully assembled antenna;
measuring the signal received by the fully assembled antenna; and
comparing the measured signal with the test signal, wherein the radio frequency signal propagates in ambient atmosphere when transmitted from the fully assembled antenna.

2. The method of claim 1 wherein generating a test signal includes generating the test signal having a WCDMA waveform.

3. The method of claim 1 wherein transmitting the test signal to the fully assembled antenna includes transmitting the test signal via a fiber optic signal to the fully assembled antenna.

4. The method of claim 1 wherein transmitting the test signal to the fully assembled antenna includes transmitting the test signal to a transceiver under test in the fully assembled antenna, and wherein the fully assembled antenna transmitting the radio frequency signal includes the transceiver under test in the fully assembled antenna transmitting the radio frequency signal, via a corresponding radiating element.

5. The method of claim 1 wherein receiving the signal transmitting by the fully assembled antenna includes an electromagnetic probe receiving the signal transmitted by the fully assembled antenna, wherein the electromagnetic probe is disposed adjacent to an area of the fully assembled antenna corresponding to a transceiver under test in the fully assembled antenna.

6. A method comprising:
generating a test signal;
transmitting the test signal to an electromagnetic probe;
the electromagnetic probe transmitting the test signal via radio frequency;
a fully assembled antenna receiving a radio frequency signal from the electromagnetic probe;
measuring the radio frequency signal received by the fully assembled antenna; and
comparing the measured signal with the test signal, wherein the test signal propagates in ambient atmosphere when transmitted from the electromagnetic probe.

7. The method of claim 2 wherein generating the test signal includes generating the test signal having a WCDMA waveform.

8. The method of claim 6 wherein transmitting the test signal to the electromagnetic probe includes transmitting the test signal via a fiber optic cable to the electromagnetic probe.

9. The method of claim 6 wherein the electromagnetic probe transmitting the test signal via radio frequency includes placing the electromagnetic probe adjacent to an area of the fully assembled antenna corresponding to a transceiver under test in the fully assembled antenna, and transmitting the test signal via radio frequency to the transceiver under test in the fully assembled antenna.

10. The method of claim 6 wherein a fully assembled antenna receiving the radio frequency signal includes a transceiver under test in the fully assembled antenna receiving the radio frequency signal.

11. A method comprising:
obtaining reference amplitude and phase;
each transceiver in a fully assembled antenna transmitting, via corresponding radiating elements, a radio frequency signal;
successively measuring amplitude and phase of the radio frequency signal transmitted by each of the transceivers in the fully assembled antenna, via the corresponding radiating elements, relative to the reference amplitude and phase; and
estimating a beam pattern transmitted by the fully assembled antenna, wherein the radio frequency signal transmitted from each transceiver propagates in ambient atmosphere for measurement.

12. The method of claim 11 wherein obtaining the reference amplitude and phase includes a first transceiver in the fully assembled antenna transmitting, via a first radiating element, a first radio frequency signal, and measuring amplitude and phase of the first radio frequency signal transmitting by the first transceiver via the first radiating element.

13. The method of claim 11 wherein obtaining the reference amplitude and phase includes obtaining the reference amplitude and phase with a first electromagnetic probe, and wherein successively measuring the amplitude and phase of the radio frequency signal transmitted by each of the transceivers in the fully assembled antenna, via the corresponding radiating elements, relative to the reference amplitude and phase includes a second electromagnetic probe successively measuring the amplitude and phase of the radio frequency signal transmitted by each of the transceivers in the fully assembled antenna, via the corresponding radiating elements, relative to the reference amplitude and phase.

14. The method of claim 11 wherein estimating the beam pattern transmitted by the fully assembled antenna includes estimating the beam transmitted by the fully assembled antenna using the successively measured amplitude and phase, a fixed distance between the fully assembled antenna and an electromagnetic probe measuring the amplitude and phase, and a predetermined frequency.

15. A method comprising:
generating a pure test tone;
transmitting the pure test tone to an electromagnetic probe;
the electromagnetic probe successively transmitting the pure test tone to a fully assembled antenna;
successively measuring amplitude and phase of a signal received by the fully assembled antenna; and
estimating a beam pattern received by the fully assembled antenna, wherein the pure test tone transmitted from the electromagnetic probe propagates in ambient atmosphere from the electromagnetic probe to the fully assembled antenna.

16. The method of claim 15 wherein the electromagnetic probe successively transmitting the pure test tone to the fully assembled antenna includes successively placing the electromagnetic probe adjacent to an area of the fully assembled antenna corresponding to radiating elements in the fully assembled antenna, and successively transmitting the pure test tone to transceivers in the antenna corresponding to the radiating elements.

17. The method of claim 15 wherein successively measuring amplitude and phase of a signal received by the fully assembled antenna includes successively measuring the amplitude and phase of the signal received by transceivers in the fully assembled antenna.

18. The method of claim 15 wherein estimating the beam pattern received by the fully assembled antenna includes estimating the beam pattern received by the fully assembled antenna using the successively measured amplitude and phase, a fixed distance between the electromagnetic probe and the fully assembled antenna, and a predetermined frequency.

19. A method comprising
generating a wave tone with known amplitude and phase;
transmitting the wave tone with known amplitude and phase to an electromagnetic probe;
the electromagnetic probe transmitting the wave tone with known amplitude and phase to a fully assembled antenna;
measuring a power level of a signal received by the fully assembled antenna; and
calibrating the fully assembled antenna, wherein the wave tone transmitted from the electromagnetic probe propagates in ambient atmosphere from the electromagnetic probe to the fully assembled antenna.

20. The method of claim 19 wherein measuring the power level of the signal received by the fully assembled antenna includes measuring the power level of the signal received by a receive path under test.

21. The method of claim 19 wherein calibrating the fully assembled antenna includes calibrating a receive path of the fully assembled antenna under test.

22. The method of claim 19 wherein calibrating the fully assembled antenna includes calibrating the fully assembled antenna using the measured power level and the known amplitude and phase of the transmitted wave tone.

23. A method comprising:
a fully assembled antenna transmitting a first signal with known amplitude and phase;
measurement equipment receiving a second signal from the fully assembled antenna;
measuring amplitude and phase of the second signal received by the measurement equipment; and
calibrating the fully assembled antenna, wherein the first signal transmitted by the fully assembled antenna propagates in ambient atmosphere from the fully assembled antenna to the measurement equipment.

24. The method of claim 23 wherein the fully assembled antenna transmitting the first signal includes the fully assembled antenna transmitting the first signal via a transmit path under test in the fully assembled antenna.

25. The method of claim 23 wherein the measurement receiving the second signal includes an electromagnetic probe receiving the second signal.

26. The method of claim 23 wherein calibrating the fully assembled antenna includes calibrating a transmit path under test in the fully assembled antenna.

27. The method of claim 23 where in calibrating the fully assembled antenna includes calibrating the fully assembled antenna using the measured amplitude and phase and the known amplitude and phase.

28. A method for testing a fully assembled antenna comprising:
an electromagnetic probe transmitting and receiving known radio frequency signals propagating in ambient air to and from the fully assembled antenna; and
measuring signals transmitted by and received at the fully assembled antenna and the electromagnetic probe.

29. The method for testing the fully assembled antenna of claim 28 further comprising measuring a third order product in a receive path of the fully assembled antenna.

30. The method for testing the fully assembled antenna of claim 28 further comprising aligning the electromagnetic probe to be co-polarized with a radiating element under test in the fully assembled antenna, and measuring a co-polarized transmit path of the fully assembled antenna.

31. The method of testing the fully assembled antenna of claim 28 further comprising aligning the electromagnetic probe to be cross-polarized with a radiating element under test in the fully assembled antenna, and measuring a cross-polarized transmit path of the fully assembled antenna.

32. The method of testing the fully assembled antenna of claim 28 further comprising aligning the electromagnetic probe to be co-polarized with a radiating element under test in the fully assembled antenna, and measuring a co-polarized receive path of the fully assembled antenna.

33. The method of testing the fully assembled antenna of claim 28 further comprising aligning the electromagnetic probe to be cross-polarized with a radiating element under test in the fully assembled antenna, and measuring a cross-polarized receive path of the fully assembled antenna.

34. The method of testing the fully assembled antenna of claim 28 further comprising measuring transmit path co-polarized isolation measurement between first and second dipoles of the fully assembled antenna.

35. The method of testing the fully assembled antenna of claim 34 wherein the first and second dipoles are adjacent.

36. The method of testing the fully assembled antenna of claim 28 further comprising measuring receive path co-polarized isolation between adjacent dipoles of the fully assembled antenna.

37. The method of testing the fully assembled antenna of claim 36 wherein the first and second dipoles are adjacent.

38. The method of testing the fully assembled antenna of claim 28 further comprising characterizing a transmit filter path of a duplexer in the fully assembled antenna.

39. The method of testing the fully assembled antenna of claim 28 further comprising characterizing a receive filter path of a duplexer in the fully assembled antenna.

40. A system comprising:
a fully assembled active digital radio antenna; and
an electromagnetic probe, wherein the electromagnetic probe transmits and receives known radio frequency signals propagated in ambient air to and from the fully assembled antenna, and wherein signals transmitted by and received at the fully assembled antenna and the electromagnetic probe are measured.
